(19) United States
(12) Patent Application Publication
(10) Pub. No.: US 2026/0060107 A1
(43) Pub. Date: Feb. 26, 2026

(54) CONNECTION PANEL UNIT AND DISPLAY DEVICE INCLUDING THE SAME

(71) Applicant: Samsung Display Co., Ltd., Yongin-Si (KR)

(72) Inventor: Dae Geun LEE, Yongin-si (KR)

(21) Appl. No.: 19/029,516

(22) Filed: Jan. 17, 2025

(30) Foreign Application Priority Data
Aug. 22, 2024 (KR) 10-2024-0112864

(51) Int. Cl. H01L 23/498; H01L 23/00

(52) U.S. Cl. CPC H01L 23/49838; H01L 24/05; H01L 24/06; H01L 24/13; H01L 2224/05017; H01L 2224/05083; H01L 2224/0519; H01L 2224/05558; H01L 2224/05573; H01L 2224/06155; H01L 2224/13019

(57) ABSTRACT

A connection panel unit and a display device including the same are disclosed. The connection panel unit includes a connection panel having a chip coupling region and a link region, a pad coupled to the chip coupling region, and a display driver chip coupled to the pad. The chip coupling region includes an input region and an output region spaced apart from each other. The pads include input pads coupled to the input region and output pads coupled to the output region. The ratio of pressure applied to the output pads to the pressure applied to the input pads may be between 0.9 and 1.1. The present disclosure can form an improved contact between a display driver chip and a connection panel.

### CROSS-REFERENCE TO RELATED APPLICATION AND CLAIM OF PRIORITY

This application claims priority to Korean Patent Application No. 10-2024-0112864 filed on August 22, 2024 in the Korean Intellectual Property Office (KIPO), the entire disclosure of which is incorporated by reference herein.

### TECHINICAL FIELD

The disclosure of this patent application relates to a connection panel unit and a display device including the same.

### BACKGROUND

In a display device, a display driver chip driving a display panel may be coupled to a connection panel. The coupling is sometimes compromised by sub-optimal contact between the display driver chip and the connection panel. A more reliable coupling between the display driver chip and the connection panel is desired.

### SUMMARY

According to an aspect of the present disclosure, there are provided a connection panel unit and a display device including the same that enhance the connection between a display driver chip and a connection panel by making the contact region uniform.

A display device comprises a connection panel including a chip coupling region and a link region, a pad coupled to the chip coupling region, and a display driver chip coupled to the pad.

The chip coupling region includes an input region and an output region spaced apart from the input region, and the pad includes a plurality of input pads coupled to the input region and a plurality of output pads coupled to the output region. A ratio of pressure applied to the plurality of output pads to pressure applied to the plurality of input pads is greater than or equal to 0.8 and less than or equal to 1.2.

In some embodiments, the ratio may be greater than or equal to 0.9 and less than or equal to 1.1.

In some embodiments, the chip coupling region may include a first long side and a second long side extending in a longitudinal direction and spaced apart from each other, and a first short side and a second short side connecting the first long side and the second long side and spaced apart from each other. The first long side, the first short side, the second long side, and the second short side may define the chip coupling region.

In some embodiments, the first long side, the first short side, the second long side, and the second short side may be connected sequentially.

In some embodiments, the input region may extend in the longitudinal direction and may be closer to the first long side than to the second long side, and the output region may extend in the longitudinal direction and may be closer to the second long side than to the first long side.

In some embodiments, at least one of the plurality of input pads and at least one of the plurality of output pads may include a base in contact with the chip coupling region, a bump coupled to the display driver chip, and a terminal positioned between the base and the bump and configured to electrically connect the base and the bump.

In some embodiments, the terminal may include a terminal shoulder in contact with the base and a terminal head protruding from the terminal shoulder and contacting the bump.

In some embodiments, an outer surface of the terminal head may be in contact with the bump and may be convex, and an inner surface of the terminal head may face the base.

In some embodiments, the display device may further comprise a buffer positioned between the terminal head and the base, and the buffer being compressible.

In some embodiments, the display device may further comprise a stand positioned between the terminal and the base. The terminal may include a terminal shoulder in contact with the stand, a terminal head protruding from the terminal shoulder and contacting the bump, and a terminal leg extending from the terminal shoulder toward the base.

In some embodiments, the stand may electrically connect the terminal and the base.

An electronic device includes a connection panel including a chip coupling region and a link region, a plurality of pads coupled to the chip coupling region, and a display driver chip coupled to the plurality of pads. The chip coupling region includes an input region and an output region spaced apart from the input region. The plurality of pads includes a plurality of input pads coupled to the input region and a plurality of output pads coupled to the output region. A ratio of an output area formed by the plurality of output pads to an input area formed by the plurality of input pads is greater than or equal to 0.9 and less than or equal to 1.1.

In some embodiments, each of the plurality of pads may include a base in contact with the chip coupling region, a bump coupled to the display driver chip, and a terminal positioned between the base and the bump and configured to electrically connect the base and the bump.

In some embodiments, the input area may be a product of a number of the plurality of input pads, a number of terminals included in each of the plurality of input pads, and an area of the terminal, and the output area may be a product of a number of the plurality of output pads, a number of the terminals included in each of the plurality of output pads, and the area of the terminal.

In some embodiments, the terminal may include a terminal shoulder connected to the base and a terminal head protruding from the terminal shoulder and contacting the bump.

A connection panel unit comprises a connection panel including a chip coupling region and a link region, and a plurality of pads coupled to the chip coupling region. Each of the plurality of pads includes a base in contact with the chip coupling region, and a terminal covering at least a portion of the base. The terminal includes a terminal shoulder electrically connected to the base, and a terminal head extending from the terminal shoulder, the terminal head being convex. The chip coupling region includes an input region and an output region spaced apart from the input region. An input area is an area of the terminal heads of a plurality of input pads coupled to the input region among the plurality of pads, and an output area is an area of the terminal heads of a plurality of output pads coupled to the output region among the plurality of pads. A ratio of the output area to the input area is greater than or equal to 0.9 and less than or equal to 1.1.

In some embodiments, an inner surface of the terminal head may face the base.

In some embodiments, the terminal head may be compressible.

In some embodiments, the connection panel unit may further comprise a buffer that is compressible and positioned between the terminal head and the base.

In some embodiments, the connection panel unit may further comprise a stand positioned between the terminal and the base and configured to electrically connect the terminal and the base, and a buffer that is compressible and positioned between the stand and the terminal head.

A connection panel unit and a display device including the same according to an embodiment of the present disclosure can more uniformly form a distribution of a region where a display driver chip and a connection panel are in contact with each other.

### BRIEF DESCRIPTION OF THE DRAWINGS

The accompanying drawings, which are included to provide a further understanding of the disclosure and are incorporated in and constitute a part of the disclosure, illustrate embodiments of the disclosure and together with the description serve to explain the principle of the disclosure.

FIG. 1 illustrates a display device.

FIG. 2 illustrates a connection panel of a connection panel unit illustrated in FIG. 1.

FIG. 3 illustrates that a portion to which a pad is coupled is displayed on a chip coupling region.

FIG. 4 illustrates that a pad is coupled to a chip coupling region illustrated in FIG. 3.

FIG. 5 illustrates a cross section of a connection panel unit illustrated in FIG. 4 taken along A1-A2.

FIG. 6 illustrates a part of a connection panel unit illustrated in FIG. 5.

FIG. 7 illustrates that a stand is included in a pad as a cross section of a connection panel unit illustrated in FIG. 4 taken along A1-A2.

FIG. 8 illustrates a part of a connection panel unit illustrated in FIG. 7.

### DETAILED DESCRIPTION OF THE EMBODIMENTS

In the present disclosure, an XYZ coordinate system as a cartesian coordinate system may be displayed in the drawings. For example, a positive Z-axis direction may indicate an upward direction, and a negative Z-axis direction may indicate a downward direction. For example, a positive Y-axis direction may indicate a forward direction, and a negative Y-axis direction may indicate a rearward direction. For example, a positive X-axis direction may indicate a right direction, and a negative X-axis direction may indicate a left direction.

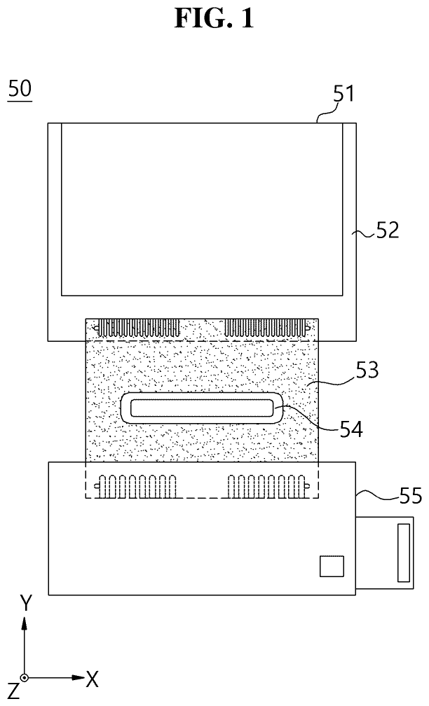

FIG. 1 illustrates a display device. Referring to FIG. 1, a display device 50 may include a display panel 51. The display panel 51 may include a plurality of pixels. The display panel 51 may display an image or a video.

The display device 50 may include a display substrate 52. The display substrate 52 may be coupled to the display panel 51. The display substrate 52 may support the display panel 51. For example, the display substrate 52 may be formed of a glass or polymer material.

The display device 50 may include a connection panel unit 53 and a display driver chip 54. The display driver chip 54 may be coupled to the connection panel unit 53.

The display driver chip 54 may be connected to the display panel 51 and may drive the display panel 51. For example, the display driver chip 54 may be connected to the display panel 51 through the connection panel unit 53.

The connection panel unit 53 may be a film. The connection panel unit 53 may be coupled to the display substrate 52. The connection panel unit 53 may be flexible, and may include the connection panel unit 53. The connection panel unit 53 may be electrically connected to the display panel 51.

The display device 50 may include a flexible printed circuit board (FPCB) 55. The FPCB 55 may be coupled to the connection panel unit 53. For example, an end of the connection panel unit 53 may be coupled to the display substrate 52, and another end of the connection panel unit 53 may be connected to the FPCB 55.

The FPCB 55 may receive an electrical signal from the outside. The electrical signal received by the FPCB 55 may be transmitted to the display driver chip 54 via the connection panel unit 53. The display driver chip 54 may drive the display panel 51 in response to the electrical signal.

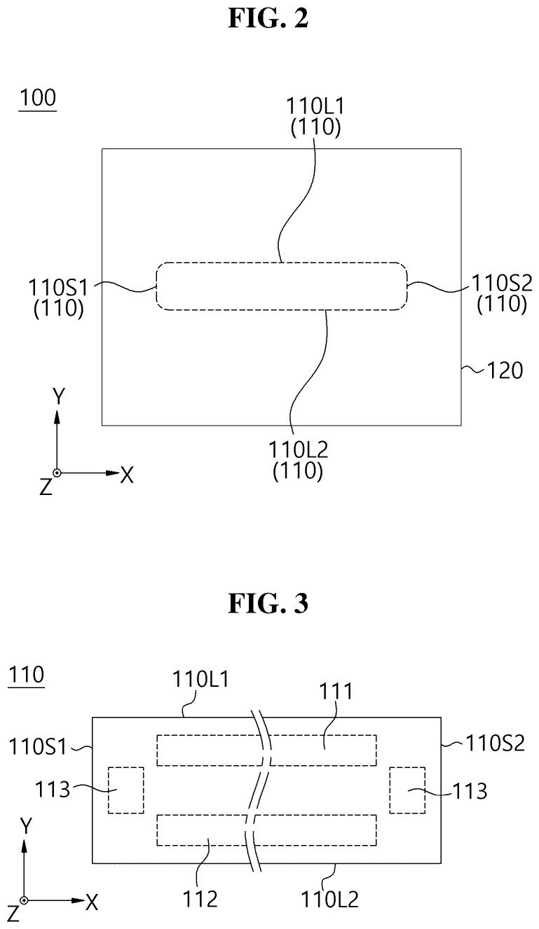

FIG. 2 illustrates a connection panel of the connection panel unit illustrated in FIG. 1.

Referring to FIG. 2, the connection panel unit 53 of FIG. 1 may include a connection panel 100. The connection panel 100 may be flexible. For example, the connection panel 100 may be a film or sheet.

The connection panel 100 may form both surfaces. For example, an upper surface of the connection panel 100 may be directed or face upward. FIG. 2 shows the upper surface of the connection panel 100.

In some embodiments, a lower surface of the connection panel 100 may face downward. A thickness of the connection panel 100 may refer to a distance between the upper surface and the lower surface of the connection panel 100.

The connection panel 100 may be divided into multiple regions. For example, a chip coupling region 110 in the area of the connection panel 100 may be a region to which the display driver chip 54 (see FIG. 1) is coupled.

For example, the region of the connection panel 100 excluding the chip coupling region 110 may be a link region 120. For example, the link region 120 may surround the chip coupling region 110. For example, the link region 120 may be adjacent to and share a border with the connection panel 100. A perimeter of the chip coupling region 110 may form a boundary between the chip coupling region 110 and the link region 120.

The chip coupling region 110 may extend in one direction. For example, the chip coupling region 110 may extend in a longitudinal direction. For example, the longitudinal direction of the chip coupling region 110 may be parallel to the X-axis direction.

The perimeter of the chip coupling region 110 may be divided into a plurality of parts. For example, the perimeter of the chip coupling region 110 may be divided into a first long side 110L1, a second long side 110L2, a first short side 110S1, and a second short side 110S2.

The first long side 110L1 and the second long side 110L2 may extend in the longitudinal direction of the chip coupling region 110. The first long side 110L1 and the second long side 110L2 may be spaced apart from each other.

A distance between the first long side 110L1 and the second long side 110L2 may be a width of the chip coupling region 110. The long sides 110L1 and 110L2 may include or indicate at least one of the first long side 110L1 and the second long side 110L2. Lengths of the long sides 110L1 and 110L2 may be a length of the chip coupling region 110.

The first short side 110S1 and the second short side 110S2 may extend in a width direction of the chip coupling region 110. The short sides 110S1 and 110S2 may include or indicate at least one of the first short side 110S1 and the second short side 110S2.

The short sides 110S1 and 110S2 may be connected to the long sides 110L1 and 110L2. For example, the first long side 110L1, the first short side 110S1, the second long side 110L2, and the second short side 110S2 may be connected sequentially.

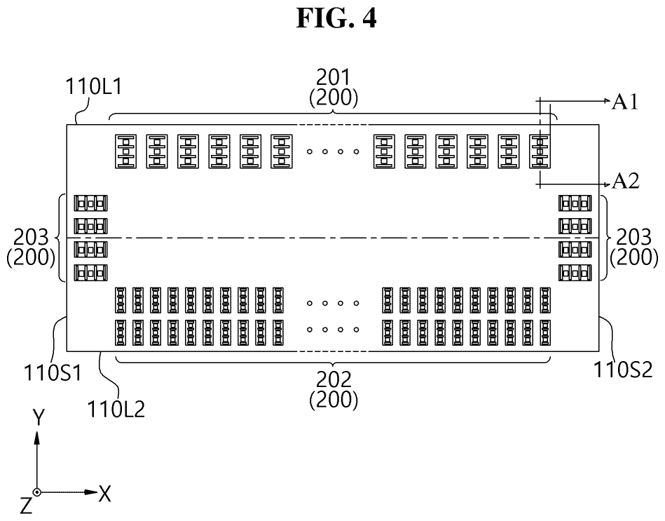

FIG. 3 illustrates that a portion to which a pad is coupled is displayed on a chip coupling region. FIG. 4 illustrates that a pad is coupled to a chip coupling region illustrated in FIG. 3.

Referring to FIGS. 3 and 4, the connection panel unit 53 may include a pad 200. The pad 200 may be coupled to the display driver chip 54 (see FIG. 1).

For example, the display driver chip 54 (see FIG. 1) may cover the pad 200 and be coupled to the pad 200. For example, the display driver chip 54 (see FIG. 1) may press the pad 200 and be coupled to the pad 200.

The pad 200 may be coupled to or formed on the connection panel 100 (see FIG. 2). For example, the pad 200 may be coupled to or formed on the chip coupling region 110.

The pad 200 may be coupled to a part of the chip coupling region 110. For example, the chip coupling region 110 may include an input region 111. A signal transmitted to the input region 111 from the FPCB 55 (see FIG. 1) may be an input signal.

The input signal may be sequentially transmitted to the pad 200 and the display driver chip 54 (see FIG. 1). The display driver chip 54 (see FIG. 1) may process the input signal to generate an output signal.

For example, the chip coupling region 110 may include an output region 112. The display driver chip 54 (see FIG. 1) may transmit the output signal to the pad 200.

The output signal transmitted to the pad 200 may be transmitted to the display panel 51 (see FIG. 1) via the output region 112. The output signal may be a signal related to the image display on the display panel 51 (see FIG. 1).

For example, the chip coupling region 110 may include a side region 113. Signals going in and out of the side region 113 may include information on a state of the display panel 51, etc. The side region 113 may be adjacent to the short sides 110S1 and 110S2.

The input region 111 and the output region 112 may extend in one direction. For example, the input region 111 and the output region 112 may extend along the long sides 110L1 and 110L2.

For example, the input region 111 may be adjacent to the first long side 110L1, and the output region 112 may be adjacent to the second long side 110L2. The input region 111 and the output region 112 may be arranged side by side. A plurality of pads 200 may be provided in the chip coupling region 110. For example, the pad 200 may include an input pad 201. A plurality of input pads 201 may be provided. The plurality of input pads 201 may be positioned or coupled to the input region 111.

For example, the pad 200 may include an output pad 202. A plurality of output pads 202 may be provided. The plurality of output pads 202 may be positioned or coupled to the output region 112.

The pad 200 may include a side pad 203. A plurality of side pads 203 may be provided. The plurality of side pads 203 may be positioned or coupled to the side region 113.

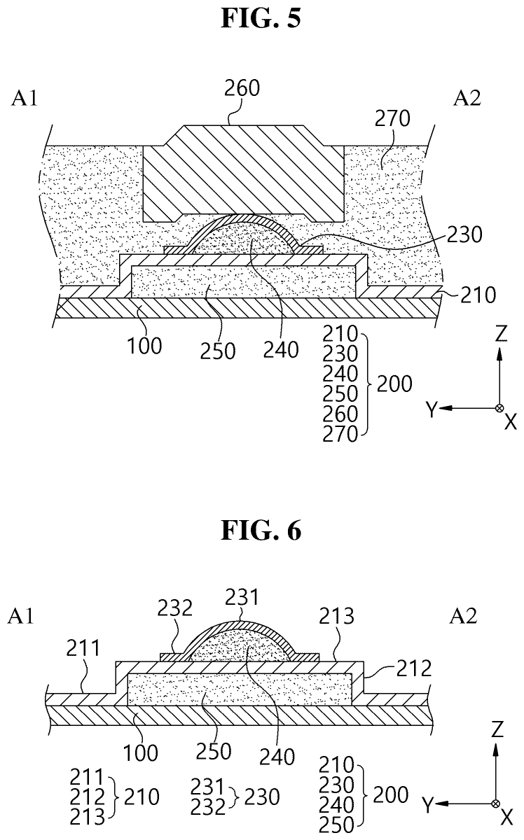

FIG. 5 illustrates a cross section of a connection panel unit illustrated in FIG. 4 taken along A1-A2. FIG. 6 illustrates a part of a connection panel unit illustrated in FIG. 5.

Referring to FIGS. 5 and 6, the pad 200 may include a base 210. The base 210 may be electrically connected to the connection panel 100. The base 210 may be formed or coupled to the connection panel 100.

For example, a lower surface of the base 210 may be coupled or attached to the upper surface of the connection panel 100. For example, the base 210 may include a base body 211. A lower surface of the base body 211 may be coupled or attached to the upper surface of the connection panel 100.

The base 210 may have a raised portion where the base 210 is farther from the connection panel 100 than other portions. For example, as depicted in the embodiments of FIG. 5 and FIG. 6, the base 210 may include the base body 211 in contact with the connection panel 100 and a base wall 212 that extends from the base body 211 away from the connection panel 100.

The base 210 may include a base loop 213. The base loop 213 may extend between two parts of the base wall 212, and be positioned farther away from the connection panel 100 than the base body 211. For example, the base loop 213 and the base wall 212 may be connected to each other. For example, a lower surface of the base loop 213 and an inner surface of the base wall 212 may be connected to each other. In the embodiments of FIG. 5 and FIG. 6, the base loop 213 is shown as having a flat surface. However, the shapes shown in the figures are examples and should not be limiting.

The pad 200 may include a pillar 250. The pillar 250 may be positioned between the base 210 and the connection panel 100. For example, the pillar 250 may be positioned between the base loop 213 and the connection panel 100, enclosed by the connection panel 100, the base wall 212, and the base loop 213.

The pillar 250 may be coupled to the connection panel 100. The pillar 250 may be disposed directly on the connection panel 100. The pillar 250 may guide a position of the base 210 in a process of coupling the base 210 to the connection panel 100.

The pad 200 may include a terminal 230. The terminal 230 may be electrically connected to the base 210. For example, the terminal 230 may be positioned on the upper surface of the base loop 213. For example, the terminal 230 may cover at least a portion of the base 210.

The terminal 230 may include a terminal head 231. The terminal head 231 may be convex or dome shaped, protruding away from the connection panel 100.

The terminal head 231 may be formed of a material containing metal. For example, the terminal head 231 may be formed of a metal plate.

The terminal 230 may include a terminal shoulder 232. The terminal shoulder 232 may extend from the edge of a perimeter of the terminal head 231. For example, the terminal shoulder 232 may be electrically connected to the base 210. For example, a lower surface of the terminal shoulder 232 may be in contact with the upper surface of the base loop 213.

The pad 200 may include a bump 260. The bump 260 may be positioned on the terminal head 231. For example, a lower surface of the bump 260 may be in contact with an upper surface or the outer surface of the terminal head 231.

The bump 260 may be in contact with the display driver chip 54 (see FIG. 1). For example, an upper surface of the bump 260 may be in contact with the display driver chip 54 (see FIG. 1).

The pad 200 may include an adhesive part 270. The adhesive part 270 may be non-conductive. For example, the adhesive part 270 may be formed of a material containing a polymer.

The adhesive part 270 may couple the base 210 and the display driver chip 54 (see FIG. 1). The adhesive part 270 may fix the terminal 230 and the bump 260 to the base 210.

The pad 200 may include a buffer 240. The buffer 240 may be positioned between the terminal 230 and the base 210. The buffer 240 may be compressible or flexible. The buffer 240 may be formed of a non-conductive material. For example, the buffer 240 may be formed of a material including a polymer.

The bump 260 may apply a pressure to the terminal 230. When a pressure toward the connection panel 100 is applied to the terminal 230, the shape of the terminal head 231 may change.

For example, in response to the pressure toward the connection panel 100 applied to the bump 260, at least a portion of the terminal head 231 that is dome-shaped in the absence of the pressure may be flattened at the top. As the dome portion becomes flattened, the contact area between the terminal head 231 and the bump 260 may increase.

The contact area between the terminal head 231 and the bump 260 may vary depending on the shape and size of the terminal head 231. The size of the terminal head 231 may correspond to an area formed by the perimeter of the terminal head 231. A boundary between the terminal head 231 and the terminal shoulder 232 may form the perimeter of the terminal head 231.

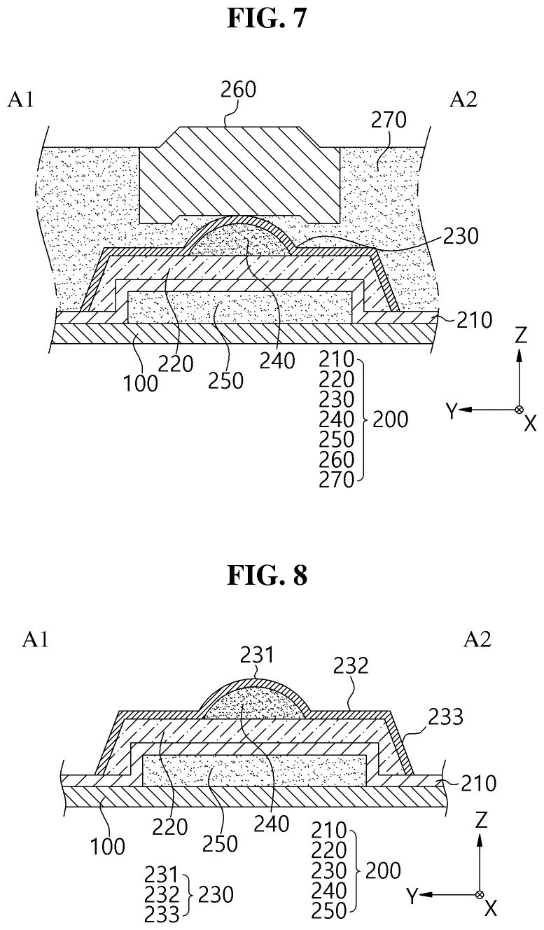

FIG. 7 illustrates a stand included in a pad as a cross section of a connection panel unit illustrated in FIG. 4 taken along A1-A2. FIG. 8 illustrates a part of a connection panel unit illustrated in FIG. 7.

Referring to FIGS. 7 and 8, the pad 200 may include a stand 220. The stand 220 may be positioned between the base 210 and the terminal 230. For example, the stand 220 may electrically connect the base 210 and the terminal 230.

The stand 220 may cover the base 210. For example, the stand 220 may cover the base loop 213 (see FIG. 6) and the base wall 212 (see FIG. 5).

The terminal 230 may cover the stand 220. For example, the lower surface of the terminal shoulder 232 may be in contact with an upper surface of the stand 220. For example, the terminal 230 may include a terminal leg 233 facing a side of the stand 220. The terminal leg 233 may extend from the terminal shoulder 232.

Referring to FIGS. 1 to 8, pressure may be applied to the display driver chip 54 toward the connection panel 100 in a state where the display driver chip 54 is in contact with the upper surface of the bump 260.

Some of the pressure applied to the display driver chip 54 may be trasnferred to the adhesive part 270. Heat may be applied to the adhesive part 270 while the pressure is applied to the adhesive part 270.

Before the heat and pressure are applied to the adhesive part 2700, the adhesive part 270 may be solid. When the heat and pressure are applied to the adhesive part 270, the adhesive part 270 may soften or melt. When the adhesive part 270 cools down, the adhesive part 270 may become solid again.

Some of the pressure applied to the display driver chip 54 may be transmitted to the terminal head 231 through the bump 260. When the pressure is applied to the terminal head 231, the dome-shaped portion of the terminal head 231 may flatten in response. With the flattening, a contact area between the terminal head 231 and the bump 260 may increase.

The pressure applied to the display driver chip 54 may be transferred to the chip coupling region 110. For example, some of the pressure applied to the display driver chip 54 may be distributed and transferred to the input region 111 and the output region 112.

A ratio of pressure transferred to the input region 111 and the output region 112 may vary depending on the number of pads 200 positioned in the input region 111 and an area and the number of terminals 230 included in each pad 200.

For example, a ratio of a pressure transferred to the output region 112 to a pressure transmitted to the input region 111 may be proportional to a ratio of the number of output pads 202 to the number of input pads 201.

For example, the ratio of the pressure transferred to the output region 112 to the pressure transferred to the input region 111 may be proportional to a ratio of the number of terminals 230 included in the output pad 202 to the number of terminals 230 included in the input pad 201.

The ratio of the pressure transferred to the output region 112 to the pressure transferred to the input region 111 may be proportional to a ratio of an area of the terminals 230 included in the output pad 202 to an area of the terminals 230 included in the input pad 201.

The area of the terminal 230 may correlate with an area of the terminal head 231. For example, the area of the terminal 230 may refer to the area enclosed by the perimeter of the terminal head 231. The perimeter of the terminal head 231 may be formed by the boundary between the terminal head 231 and the terminal shoulder 232.

For example, the ratio of the pressure transferred to the output region 112 to the pressure transferred to the input region 111 may be optimal if it is close to one. In other words, as the ratio of the pressure transferred to the output region 112 to the pressure transferred to the input region 111 gets closer to one, the display driver chip 54 can be coupled to the connection panel unit 53 with optimal efficiency.

As used herein, an “input area” may be a product of the number of input pads 201, the number of terminals 230 included in one of the input pads 201, and the area of each terminal 230 included in the input pads 201.

As used herein, an “output area” may be a product of the number of output pads 202, the number of terminals 230 included in one of the output pads 202, and the area of each terminal 230 included in the output pads 202.

In the connection panel unit 53 according to an embodiment of the present disclosure, a ratio of the output area to the input area may be greater than or equal to a first area ratio and less than or equal to a second area ratio.

The first area ratio and the second area ratio are preselected numbers. In one embodiment, the first area ratio may be 0.8 and the second area ratio may be 1.2. For example, the first area ratio may be 0.9, and the second area ratio may be 1.1. For example, in the connection panel unit 53, the ratio of the output area to the input area may be substantially 1.

A ratio of a pressure applied to the output pad 202 to a pressure applied to the input pad 201 may correspond to the ratio of the output area to the input area. For example, the ratio of the pressure applied to the output pad 202 to the pressure applied to the input pad 201 may be the ratio of the output area to the input area.

In this context, the first area ratio may be referred to as a “first pressure ratio”, and the second area ratio may be referred to as a “second pressure ratio”.

A ratio of a contact area between the bump 260 and the terminal 230 of the output pad 202 to a contact area between the bump 260 and the terminal 230 of the input pad 201 may correspond to the ratio of the output area to the input area.

For example, the ratio of the contact area between the bump 260 and the terminal 230 of the output pad 202 to the contact area between the bump 260 and the terminal 230 of the input pad 201 may be the ratio of the output area to the input area.

Hence, the display driver chip 54 can be effectively coupled to the connection panel unit 10. As a result, the electrical connection between the display driver chip 54 and the connection panel unit 53 can be effectively maintained.

The embodiments disclosed herein may be used in a display device for displaying videos or still images. The display device may be portable electronic devices such as mobile phones, smartphones, tablet personal computers (PC), mobile communication terminals, electronic organizers, electronic books, portable multimedia players (PMP), global positioning systems, or ultra-mobile PCs (UMPC), and also for various products such as televisions, laptops, monitors, advertisement boards, or the Internet of Things (IOT). In addition, the display device according to an embodiment may be used on wearable devices such as smart watches, watch phones, glasses-type displays, or head mounted displays (HMD). In addition, the display device according to an embodiment may be used as a dashboard of a vehicle, a center information display (CID) disposed on a center fascia or a dashboard of a vehicle, a room mirror display replacing a side-view mirror of a vehicle, and a display disposed on a rear surface of a front seat for entertainment for a back seat of a vehicle.

Embodiments described herein should be considered in a descriptive sense only and not for purposes of limitation. Descriptions, features, or aspects within each embodiment should typically be considered as available for other embodiments. While one or more embodiments have been described with reference to the figures, it will be understood by those of ordinary skill in the art that various changes in form and details may be made therein without departing from the spirit and scope of the inventive concept as defined by the following claims.

What is claimed is:

1. A display device comprising:
a connection panel including a chip coupling region and a link region;
a pad coupled to the chip coupling region; and
a display driver chip coupled to the pad,
wherein the chip coupling region includes:
an input region; and
an output region spaced apart from the input region,
wherein the pad includes:
a plurality of input pads coupled to the input region; and
a plurality of output pads coupled to the output region,
wherein a ratio of pressure applied to the plurality of output pads to pressure applied to the plurality of input pads is greater than or equal to a 0.8 and less than or equal to 1.2.

2. The display device of claim 1, wherein the ratio is greater than or equal to 0.9 and less than or equal to 1.1.

3. The display device of claim 1, wherein the chip coupling region includes:
a first long side and a second long side extending in a longitudinal direction and spaced apart from each other; and
a first short side and a second short side connecting the first long side and the second long side, the first short side and the second short side being spaced apart from each other,
wherein the first long side, the first short side, the second long side, and the second short side define the chip coupling region.

4. The display device of claim 3, wherein the first long side, the first short side, the second long side, and the second short side are connected sequentially.

5. The display device of claim 3, wherein the input region extends in the longitudinal direction and is closer to the first long side than to the second long side, and
wherein the output region extends in the longitudinal direction and is closer to the second long side than to the first long side.

6. The display device of claim 1, wherein at least one of the plurality of input pads and at least one of the plurality of output pads includes:
a base in contact with the chip coupling region;
a bump coupled to the display driver chip; and
a terminal positioned between the base and the bump and configured to electrically connect the base and the bump.

7. The display device of claim 6, wherein the terminal includes:
a terminal shoulder in contact with the base; and
a terminal head protruding from the terminal shoulder and contacting the bump.

8. The display device of claim 7, wherein an outer surface of the terminal head is in contact with the bump and is convex, and
wherein an inner surface of the terminal head faces the base.

9. The display device of claim 8, further comprising:
a buffer positioned between the terminal head and the base, the buffer being compressible.

10. The display device of claim 6, further comprising:
a stand positioned between the terminal and the base,
wherein the terminal includes:
a terminal shoulder in contact with the stand;
a terminal head protruding from the terminal shoulder and contacting the bump; and
a terminal leg extending from the terminal shoulder toward the base.

11. The display device of claim 10, wherein the stand electrically connects the terminal and the base.

12. An electronic device comprising:
a connection panel including a chip coupling region and a link region;
a plurality of pads coupled to the chip coupling region; and
a display driver chip coupled to the plurality of pads,
wherein the chip coupling region includes:
an input region; and
an output region spaced apart from the input region,
wherein the plurality of pads include:
a plurality of input pads coupled to the input region; and
a plurality of output pads coupled to the output region,
wherein a ratio of an output area formed by the plurality of output pads to an input area formed by the plurality of input pads is greater than or equal to 0.9 and less than or equal to 1.1.

13. The electronic device of claim 12, wherein each of the plurality of pads includes:
a base in contact with the chip coupling region;
a bump coupled to the display driver chip; and
a terminal positioned between the base and the bump and configured to electrically connect the base and the bump.

14. The electronic device of claim 13, wherein the input area is a product of a number of the plurality of input pads, a number of terminals included in each of the plurality of input pads, and an area of the terminal, and
wherein the output area is a product of a number of the plurality of output pads, a number of terminals included in each of the plurality of output pads, and the area of the terminal.

15. The electronic device of claim 14, wherein the terminal includes:
a terminal shoulder connected to the base; and
a terminal head protruding from the terminal shoulder and contacting the bump.

16. A connection panel unit comprising:
a connection panel including a chip coupling region and a link region; and
a plurality of pads coupled to the chip coupling region,
wherein each of the plurality of pads includes:
a base in contact with the chip coupling region; and
a terminal covering at least a portion of the base,
wherein the terminal includes:
a terminal shoulder electrically connected to the base; and
a terminal head extending from the terminal shoulder, the terminal head being convex,
wherein the chip coupling region includes an input region and an output region spaced apart from the input region,
wherein an input area is an area of the terminal heads of a plurality of input pads coupled to the input region among the plurality of pads,
wherein an output area is an area of the terminal heads of a plurality of output pads coupled to the output region among the plurality of pads, and
wherein a ratio of the output area to the input area is greater than or equal to 0.9 and less than or equal to 1.1.

17. The connection panel unit of claim 16, wherein an inner surface of the terminal head faces the base.

18. The connection panel unit of claim 17, wherein the terminal head is compressible.

19. The connection panel unit of claim 17, further comprising:
a buffer that is compressible positioned between the terminal head and the base.

20. The connection panel unit of claim 17, further comprising:
a stand positioned between the terminal and the base and configured to electrically connect the terminal and the base; and
a buffer that is compressible positioned between the stand and the terminal head.
